(19) United States
(12) Patent Application Publication
(10) Pub. No.: US 2024/0269780 A1
(43) Pub. Date: Aug. 15, 2024

(54) BONDING SHEET AND METHOD FOR PRODUCING SAME

(71) Applicant: NITTO DENKO CORPORATION, Ibaraki-shi, Osaka (JP)

(72) Inventors: Masatoshi KATO, Ibaraki-shi, Osaka (JP); Ayumi NITTA, Ibaraki-shi, Osaka (JP); Naofumi KOSAKA, Ibaraki-shi, Osaka (JP)

(21) Appl. No.: 18/281,221

(22) PCT Filed: Mar. 7, 2022
(86) PCT No.: PCT/JP2022/009645

§ 371 Date: May 7, 2024

(30) Foreign Application Priority Data
Mar. 9, 2021 (JP) 2021-037818
Sep. 29, 2021 (JP) 2021-159847

(51) Int. Cl. B23K 35/02; B23K 35/26; B23K 35/362; C09J 7/35; C09J 9/02; C09J 11/04; C09J 11/06; C09J 163/00; C22C 12/00; H01R 12/52; H05K 3/36

(52) U.S. Cl. CPC B23K 35/0233; B23K 35/264; B23K 35/362; C09J 7/35; C09J 9/02; C09J 11/04; C09J 11/06; C09J 163/00; C22C 12/00; H01R 12/52; H05K 3/368; C09J 2400/16; C09J 2400/20; C09J 2433/00; C09J 2463/00; H05K 2203/048

(57) ABSTRACT

A bonding sheet according to the present invention contains a matrix resin; solder particles; and a fluxing agent. In the bonding sheet, the solder particles are dispersed in the matrix resin, and the fluxing agent is unevenly distributed around the solder particles in the matrix resin. The method for producing the bonding sheet of the present invention includes a first step of dissolving a fluxing agent in a first solvent to prepare a fluxing agent solution; a second step of mixing a second solvent, a matrix resin component, solder particles, and the fluxing agent solution to prepare a mixed composition; and a third step of applying the mixed composition onto a substrate to form a coated film, and then drying the coated film to form a bonding sheet.

### TECHNICAL FIELD

The present invention relates to a bonding sheet and a method for producing the same.

### BACKGROUND ART

Conventionally, a bonding sheet is used in bonding a terminal of a wiring circuit board to a terminal of an electronic component, and in bonding between terminals of two wiring circuit boards. For solder bonding, a bonding sheet containing solder particles, a thermoplastic resin, a thermosetting resin, and a fluxing agent is used. For example, a bonding sheet containing solder particles, a thermoplastic resin, a thermosetting resin, and a blocked carboxylic acid has been known (see, for example, Patent Document 1).

The bonding sheet is first disposed between the terminal of the wiring circuit board and the terminal of the electronic component. Then, the bonding sheet is heated. This causes the thermosetting resin to soften once, and the solder particles to gather between the terminals and be aggregated (self-alignment). Curing of the thermosetting resin progresses around the solder material where the particles are aggregated. The solder material coagulates by subsequent lowering of the temperature, to form a solder portion. The thermosetting resin forms a cured resin portion around the solder portion.

The bonding sheet described in Patent Document 1 contains the blocked carboxylic acid as a fluxing agent. The blocked carboxylic acid melts and removes oxide films on the surfaces of the solder particles in the heating step. This removal of the oxide films makes the solder particles more likely to aggregate.

### CITATION LIST

### Patent Document

Patent Document 1: Japanese Unexamined Patent Publication No. 2013-224362

### SUMMARY OF THE INVENTION

### Problem to be Solved by the Invention

However, in the bonding sheet described in Patent Document 1, the blocked carboxylic acid is uniformly dispersed throughout matrix resins (thermoplastic resin and thermosetting resin), besides around the solder particles. That is, in the bonding sheet, in addition to the fluxing agent that exists around the solder particles and contributes to the removal of the oxide films of the solder particles, there exists excess fluxing agent that does not exist around the solder particles and does not contribute to the removal of the oxide films of the solder particles. Accordingly, there is a disadvantage in that resistance values increase due to metal corrosion of the solder portion caused by such excess fluxing agent.

The present invention provides a bonding sheet that can suppress an increase in resistance of a solder portion while promoting aggregation of solder particles, thereby improving durability, and a method for producing such a bonding sheet.

### Means for Solving the Problem

The present invention [1] includes a bonding sheet, containing a matrix resin; solder particles; and a fluxing agent, the solder particles being dispersed in the matrix resin, and the fluxing agent being unevenly distributed around the solder particles in the matrix resin.

The present invention [2] includes the bonding sheet described in [1], in which the fluxing agent unevenly distributed around the solder particles contains a metal derived from the solder particles.

The present invention [3] includes the bonding sheet described in [1] or [2], in which when an oxygen concentration of the solder particles is defined as x₁ ppm and a content of the fluxing agent with respect to 100 parts by weight of the solder particles is defined as y₁ mmol, the bonding sheet satisfies the following formula (1):

$$\\ \begin{matrix}0.045 \leq {y}_{1} / {x}_{1} \leq 0.09 & ( 1 )\end{matrix}$$

The present invention [4] includes the bonding sheet described in any one of the above-described [1] to [3], in which when a median size (D₅₀) of the solder particles is defined as x₂ μm and a content of the fluxing agent with respect to 100 parts by weight of the solder particles is defined as y₂ mol, the bonding sheet satisfies the following formula (2):

$$\\ \begin{matrix}0.15 < {x}_{2} {y}_{2} < 0.3 & ( 2 )\end{matrix}$$

The present invention [5] includes the bonding sheet described in any one of the above-described [1] to [4], in which the fluxing agent is a solid carboxylic acid at 25° C.

The present invention [6] includes the bonding sheet described in any one of the above-described [1] to [5], in which the solder particles have a melting point of 150° C. or less.

The present invention [7] includes the bonding sheet described in any one of the above-described [1] to [6], having a thickness of 30 μm or less.

The present invention [8] includes a method for producing a bonding sheet, including a first step of dissolving a fluxing agent in a first solvent to prepare a fluxing agent solution; a second step of mixing a second solvent, a matrix resin component, solder particles, and the fluxing agent solution to prepare a mixed composition; and a third step of applying the mixed composition onto a substrate to form a coated film, and then drying the coated film to form a bonding sheet.

### Effects of the Invention

In the bonding sheet of the present invention, the fluxing agent is unevenly distributed around the solder particles in the matrix resin. Therefore, the oxide films on the surfaces of the solder particles can be efficiently removed and the solder particles can be aggregated. Since the fluxing agent is unevenly distributed around the solder particles, excess fluxing agent other than around the solder particles can be reduced, and the increase in resistance of the solder portion can be suppressed. As a result, durability can be improved.

The method for producing the bonding sheet according to the present invention includes the first step of preparing the fluxing agent solution by dissolving the fluxing agent in the first solvent. Therefore, the above-described bonding sheet can be reliably produced.

### BRIEF DESCRIPTION OF THE DRAWINGS

FIG. 1 shows a cross-sectional schematic view of one embodiment of a bonding sheet of the present invention.

FIGS. 2A and 2B represent some steps in one embodiment of a production method of the bonding sheet of the present invention: FIG. 2A represents a coated film forming step, and FIG. 2B represents a drying step.

FIGS. 3A to 3C represent a process diagram of one example of a solder bonding method using the bonding sheet shown in FIG. 1: FIG. 3A represents a preparation step, FIG. 3B represents a lamination step, and FIG. 3C represents a heating step.

FIG. 4 shows an image-processed scanning electron microscope (SEM) photograph of a cross section of the bonding sheet of Example 1.

FIG. 5 shows an image-processed scanning electron microscope (SEM) photograph of a cross section of the bonding sheet of Comparative Example 1.

FIG. 6 shows image-processed energy dispersive X-ray analysis (EDX) photographs of the cross section of the bonding sheet of Example 1.

FIGS. 7A to 7C show image-processed scanning electron microscope (SEM) photographs of cross sections of the bonding sheets of Example 1 and Comparative Example 2 for evaluating the flux uneven distribution state: FIGS. 7A and 7B each show an image-processed scanning electron microscope (SEM) photograph of the cross section of the bonding sheet of Example 1, and FIG. 7C shows an image-processed scanning electron microscope (SEM) photograph of the cross section of the bonding sheet of Comparative Example 2.

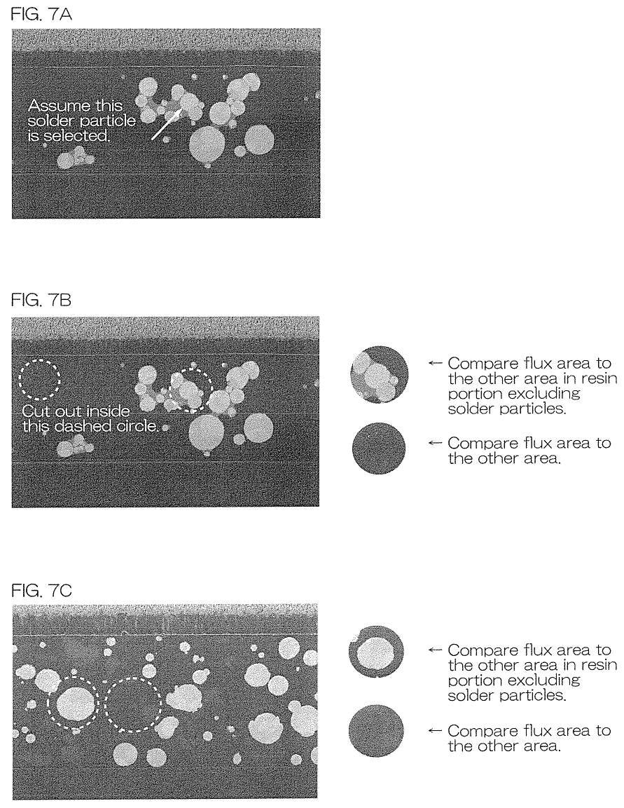

### DESCRIPTION OF THE EMBODIMENTS

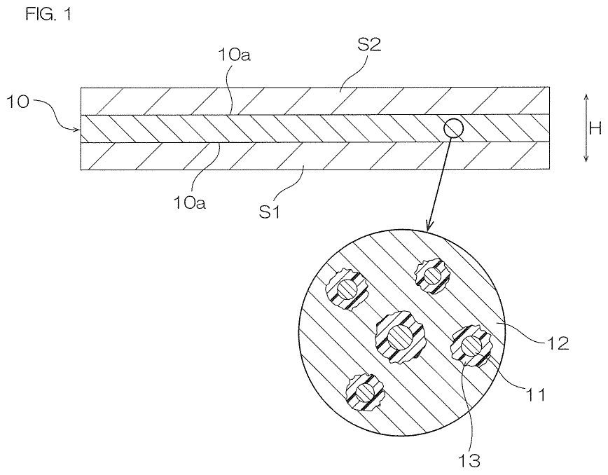

FIG. 1 shows a cross-sectional schematic view of a bonding sheet 10 as one embodiment of the bonding sheet of the present invention (a state in which the bonding sheet 10 is sandwiched between substrates S1 and S2 is illustrated). The bonding sheet 10 is used to solder-bond two objects to be bonded. The bonding sheet 10 has a sheet shape having a predetermined thickness and extends in a direction (plane direction) orthogonal to a thickness direction H. Also, the bonding sheet 10 may have a long sheet shape. When the bonding sheet 10 has a long sheet shape, it may have a roll form which is wound up. Or, the bonding sheet 10 may also have a single-sheet form.

A thickness of the bonding sheet is, for example, 30 μm or less, preferably 25 μm or less, more preferably 20 μm or less, further more preferably 15 μm or less. The thinner the bonding sheet, the more it can cope with a fine pitch of an object to be bonded. The thickness of the bonding sheet is, for example, 3 μm or more, preferably 5 μm or more from the viewpoint of handleability of the bonding sheet.

The bonding sheet contains a matrix resin, solder particles, and a fluxing agent.

The matrix resin contains a thermosetting resin and a thermoplastic resin. From the viewpoint of moldability of the bonding sheet, preferably, the thermosetting resin is liquid at room temperature (25° C.) and the thermoplastic resin is solid at room temperature (25° C.)

Examples of the thermosetting resin include epoxy resins, urea resins, melamine resins, diallyl phthalate resins, silicone resins, phenol resins, thermosetting acrylic resins, thermosetting polyesters, thermosetting polyimides, and thermosetting polyurethanes. Preferably, an epoxy resin and a thermosetting polyurethane are used, more preferably, an epoxy resin is used.

Examples of the epoxy resin include aromatic epoxy resins, nitrogen-containing-cyclic epoxy resins, aliphatic epoxy resins, alicyclic epoxy resins, glycidyl ether epoxy resins, and glycidyl amine epoxy resins.

Examples of the aromatic epoxy resin include bisphenol epoxy resins, novolac epoxy resins, fluorene epoxy resins, and triphenylmethane epoxy resins.

Examples of the bisphenol epoxy resin include bisphenol A type epoxy resin, bisphenol F type epoxy resin, bisphenol S type epoxy resin, hydrogenated bisphenol A type epoxy resin, and dimer acid modified bisphenol epoxy resin.

Examples of the novolac epoxy resin include phenol novolac epoxy resin, cresol novolac epoxy resin, and biphenyl epoxy resin.

An example of the fluorene epoxy resin include bisarylfluorene epoxy resin.

An example of the triphenylmethane epoxy resin include trishydroxyphenylmethane epoxy resin.

Examples of the nitrogen-containing-cyclic epoxy resin include triepoxypropyl isocyanurate (triglycidyl isocyanurate) and hydantoin epoxy resin.

An example of the alicyclic epoxy resin include dicyclo ring-type epoxy resin.

As the epoxy resin, commercially available products can be used. Specifically, jER (registered trademark) 828 (bisphenol A type epoxy resin, manufactured by Mitsubishi Chemical Corporation) is used.

An epoxy equivalent of the epoxy resin is, for example, 80 g/eq or more, preferably 100 g/eq or more, more preferably 150 g/eq or more, and for example, 500 g/eq or less, preferably 400 g/eq or less, more preferably 250 g/eq or less.

As the epoxy resin, preferably, a bisphenol epoxy resin which is liquid at room temperature (25° C.) is used, more preferably, a bisphenol A type epoxy resin which is liquid at room temperature (25° C.) is used.

A curing temperature of the thermosetting resin is, for example, 90° C. or more, preferably 140° C. or more, and for example, 250° C. or less, preferably 230° C. or less, more preferably 200° C. or less, further more preferably 160° C. or less.

The thermosetting resin is preferably liquid at room temperature (25° C.). When the thermosetting resin is in a liquid state at room temperature, adhesive reliability is enhanced. The term “liquid” refers to a liquid or a fluid having a viscosity of 200 Pa˜s or less at room temperature (25° C.).

These thermosetting resins can be used alone or in combination of two or more.

A ratio of the thermosetting resin in the matrix resin is, for example, 50% by mass or more, preferably 60% by mass or more, and 90% by mass or less, preferably 80% by mass or less. A ratio of the thermosetting resin in the bonding sheet is, for example, 10% by mass or more, preferably 20% by mass or more, and 50% by mass or less, preferably 30% by mass or less. When the ratio of the thermosetting resin is less than the above-described lower limit, a sufficient reinforcing effect may not be obtained after solder bonding. On the other hand, when such ratio exceeds the above-described upper limit, it may be difficult to mold the bonding sheet into a sheet form.

When the epoxy resin is used as the thermosetting resin, the matrix resin may further contain a phenol resin as a curing agent of the epoxy resin. Examples of the phenol resin include novolac phenol resins and resol phenol resins. Examples of the novolac phenol resin include phenol novolac resins, phenol aralkyl resins, cresol novolac resins, tert-butyl phenol novolac resins, and nonylphenol novolac resins.

Examples of the thermoplastic resin include polyolefins (e.g., polyethylene, polypropylene, and an ethylene-propylene copolymer), acrylic resins, phenoxy resins, polyesters, polyvinyl acetate, ethylene-vinyl acetate copolymers, polyvinyl chloride, polystyrene, polyacrylonitrile, polyamide (nylon (registered trademark)), polycarbonate, polyacetal, polyethylene terephthalate, polyphenylene oxide, polyphenylene sulfide, polysulfone, polyether sulfone, polyether ether ketone, polyallyl sulfone, thermoplastic polyimide, thermoplastic polyurethane, polyaminobismaleimide, polyamide-imide, polyetherimide, bismaleimide triazine resins, polymethylpentene, fluorine resins, liquid crystal polymers, olefin-vinyl alcohol copolymers, ionomers, polyarylate, acrylonitrile-ethylene-styrene copolymers, acrylonitrile-butadiene-styrene copolymers, acrylonitrile-styrene copolymers, and butadiene-styrene copolymers.

As the thermoplastic resin, preferably, an acrylic resin and a polyester are used, more preferably, an acrylic resin is used.

The acrylic resin is made of an acrylic polymer. The acrylic polymer is a polymer of a monomer which contains, as a main component, an alkyl (meth)acrylate containing an alkyl portion having 1 to 12 carbon atoms such as methyl (meth)acrylate, ethyl (meth)acrylate, propyl (meth)acrylate, butyl (meth)acrylate, hexyl (meth)acrylate, octyl (meth)acrylate, decyl (meth)acrylate, and dodecyl (meth)acrylate. “(Meth)acrylate” means acrylate and/or methacrylate. These monomers can be used alone or in combination.

The monomer may contain one or two or more kinds of copolymerizable monomers copolymerizable with the alkyl (meth)acrylate. The copolymerizable monomer includes a functional group-containing vinyl monomer and an aromatic vinyl monomer. The copolymerizable monomer serves to modify the acrylic polymer such as ensuring cohesive force of the acrylic polymer.

Examples of the functional group-containing vinyl monomer include carboxy group-containing vinyl monomers, acid anhydride vinyl monomers, hydroxy group-containing vinyl monomers, sulfo group-containing vinyl monomers, phosphoric acid group-containing vinyl monomers, cyano group-containing vinyl monomers, and glycidyl group-containing vinyl monomers. Preferably, a hydroxy group-containing vinyl monomer is used.

Examples of the aromatic vinyl monomer include styrene, chlorostyrene, chloromethylstyrene, and α-methylstyrene.

As the acrylic polymer, commercially available products can be used. Specifically, UH-2170 (manufactured by Toagosei Co., Ltd.) is used as a hydroxy group-containing styrene-acrylic polymer.

A glass transition temperature Tg of the acrylic resin is, for example, −100° C. or more, preferably −50° C. or more, and for example, 100° C. or less, preferably 50° C. or less.

The glass transition temperature (Tg) of the acrylic resin is determined based on the Fox equation.

A softening temperature of the thermoplastic resin is, for example, 40° C. or more, preferably 45° C. or more, more preferably 50° C. or more, most preferably 55° C. or more, and for example, 140° ° C. or less, preferably 120° C. or less, more preferably 100° C. or less, most preferably 80° C. or less.

A weight average molecular weight (Mw) of the thermoplastic resin is, for example, 8000 or more, preferably 10000 or more, and for example, 2 million or less, preferably 1.5 million or less. The weight average molecular weight (value in terms of standard polystyrene) of the acrylic resin is calculated by GPC. When the weight average molecular weight (Mw) is within the above-described range, generation of pinholes can be suppressed when the bonding sheet is molded into a sheet form.

The thermoplastic resin is preferably in a solid form (solid) at room temperature (25° C.). When the thermoplastic resin is in a solid form at room temperature, it can ensure shape retention and maintain the sheet shape of the bonded sheet.

These thermoplastic resins can be used alone or in combination of two or more.

A ratio of the thermoplastic resin in the matrix resin is, for example, 10% by mass or more, preferably 20% by mass or more, and 50% by mass or less, preferably 40% by mass or less. A ratio of the thermoplastic resin in the bonding sheet is preferably 2% by mass or more, more preferably 5% by mass or more, further more preferably 10% by mass or more, and preferably 50% by mass or less, more preferably 30% by mass or less, further more preferably 20% by mass or less. When the ratios are within the above-described ranges, both the moldability of the bonding sheet and the bonding strength of the bonding sheet with respect to an object to be bonded can be achieved.

In the matrix resin, the thermosetting resin and the thermoplastic resin are compatible with each other.

A solder material that forms the solder particles is, for example, solder metal. The solder metal includes solder materials containing no lead (lead-free solder) from the viewpoint of environmental suitability. Examples of the solder material include tin-bismuth-based alloys and tin-silver-based alloys.

Examples of the tin-bismuth-based alloy include tin-bismuth alloys (Sn—Bi) and tin-bismuth-indium alloys (Sn—Bi—In). Examples of the tin-silver-based alloy include tin-silver alloys (Sn—Ag) and tin-silver-copper alloys (Sn—Ag—Cu). From the viewpoint of low temperature bonding, as the solder material, preferably, a tin-bismuth alloy and a tin-bismuth-indium alloy are used.

A content ratio of the tin in the tin-bismuth alloy is, for example, 20% by mass or more, preferably 30% by mass or more, and for example, 50% by mass or less, preferably 45% by mass or less. A content ratio of the bismuth in the tin-bismuth alloy is, for example, 50% by mass or more, preferably 55% by mass or more, and for example, 80% by mass or less, preferably 70% by mass or less.

The solder particles have a melting point (melting point of the solder material) of, for example, 100° C. or more, preferably 130° C. or more, and for example, 240° C. or less, preferably 200° C. or less, more preferably 160° C. or less, further more preferably 150° C. or less. The melting point of the solder material can be determined by differential scanning calorimetry (DSC) (the same applies to the fluxing agent hereinafter). When the melting point of the solder particles is within the above-described range, melting of solder in a heating process during sheet formation can be suppressed. Also, during mounting by solder accumulation, the influence of heat applied to the periphery of the mounting portion can be suppressed.

Examples of a shape of the solder particle include spherical shapes, plate shapes, and needle shapes, and preferably, a spherical shape is used.

The solder particles have a median size (particle size) D₅₀ of, for example, 10 nm or more, preferably 1 μm or more. When the particle size D₅₀ is not less than the above-described lower limit, a solder portion can be appropriately formed between two objects to be bonded. The particle size D₅₀ of the solder particles is, for example, 10 μm or less, preferably 8 μm or less, more preferably 6 μm or less, further more preferably 5 μm or less, particularly preferably 4 μm or less. When the particle size D₅₀ is not more than the above-described upper limit, the dispersibility of the solder particles in the bonding sheet can be improved. Also, the bonding sheet can be made thinner. The particle size D₅₀ of the solder particles is the median size in the volume-based particle size distribution (the particle size where the volume cumulative frequency thereof reaches 50% from the smaller diameter side), and is determined based on the particle size distribution obtained by, for example, laser diffraction and scattering (the same applies to the fluxing agent hereinafter).

Generally, the surface of each of the solder particles is covered with an oxide film made of an oxide of the solder material. The oxide film has a thickness of, for example, from 1 to 20 nm.

An oxygen concentration of the solder particles can be measured by a known method, for example, by an oxygen/nitrogen analyzer (EMGA-650, manufactured by HORIBA, Ltd.). The oxygen concentration of the solder particles is preferably low. The oxygen concentration of the solder particles is, for example, 100 ppm or more, preferably 350 ppm or more, more preferably 550 ppm or more, more preferably 700 ppm or more, and for example, 3000 ppm or less, preferably 2500 ppm or less, more preferably 2000 ppm or less, further more preferably 1400 ppm or less. When the oxygen concentration of the solder particles is within the above-described range, the solder particles can be efficiently accumulated.

The solder particles can be used alone or in combination of two or more.

A content of the solder particles in the bonding sheet is, for example, 50 parts by mass or more, preferably 100 parts by mass or more, more preferably 120 parts by mass or more with respect to 100 parts by mass of the matrix resin. A ratio of the solder particles in the bonding sheet is, for example, 5% by mass or more, preferably 10% by mass or more, more preferably 20% by mass or more, further more preferably 30% by mass or more, particularly preferably 40% by mass or more, most preferably 50% by mass or more. When the content of the solder particles is not less than the above-described lower limit, cohesiveness of the solder particles in the solder bonding process can be ensured. Also, the content of the solder particles in the bonding sheet is, for example, 600 parts by mass or less, preferably 450 parts by mass or less, more preferably 170 parts by mass or less with respect to 100 parts by mass of the matrix resin. Also, the ratio of the solder particles in the bonding sheet is, for example, 80% by mass or less, preferably 70% by mass or less, more preferably 60% by mass or less. When the content of the solder particles is not more than the above-described upper limit, the moldability of the bonding sheet is excellent.

The solder particles are uniformly dispersed in the matrix resin. That is, the solder particles are distributed in a uniform concentration in the matrix resin. The “uniform concentration” has a distribution range of +20%, preferably +10%, with respect to a reference concentration based on the content of the solder particles in the matrix resin. The concentration distribution can be observed, for example, by a scanning electron microscope (SEM).

When the solder particles are melted by heating, the fluxing agent removes (activates) the oxide films on the surfaces of the solder particles.

Examples of the fluxing agent include organic acids, quinolinol derivatives, and metal carbonyl acid salts. Examples of the organic acid include carboxylic acids. Examples of the carboxylic acid include monocarboxylic acid, dicarboxylic acid, and tricarboxylic acid. Examples of the monocarboxylic acid include glycolic acid, lactic acid, and 2-hydroxybutanoic acid. Examples of the dicarboxylic acid include tartaric acid, malic acid, adipic acid, malonic acid, succinic acid, glutaric acid, pimelic acid, suberic acid, and sebacic acid. An example of the tricarboxylic acid include citric acid. From the viewpoint of such an oxide film removal function, the fluxing agent is preferably carboxylic acid, more preferably dicarboxylic acid, further more preferably malic acid and malonic acid.

From the viewpoint of the moldability of the bonding sheet, the fluxing agent is preferably solid at 25° C. The fluxing agent has a melting point of higher than 25° C., preferably 80° C. or more, more preferably 100° C. or more, further more preferably 120° C. or more. The melting point of the fluxing agent is, for example, 200° C. or less, preferably 180° C. or less, more preferably 160° C. or less. From the viewpoint of achieving both the moldability of the bonding sheet and the above-described oxide film removal function, the fluxing agent is preferably a solid carboxylic acid at 25° C.

A shape of the fluxing agent is not particularly limited, and examples of the shape thereof include plate shapes, needle shapes, and spherical shapes.

The fluxing agent has a particle size D₅₀ of, for example, 2 μm or more, preferably 3 μm or more, and for example, 20 μm or less, preferably 10 μm or less, more preferably 6 μm or less. When the particle size D₅₀ of the fluxing agent is within the above-described range, the dispersibility of the fluxing agent can be improved.

These fluxing agents can be used alone or in combination of two or more.

A content of the fluxing agent in the bonding sheet is, for example, 1 part by mass or more, preferably 5 parts by mass or more, more preferably 7.5 parts by mass or more, further more preferably 10 parts by mass or more with respect to 100 parts by mass of the matrix resin. Also, a ratio of the fluxing agent in the bonding sheet 10 is, for example, 1% by mass or more, preferably 2% by mass or more, more preferably 3% by mass or more. When the content of the fluxing agent is not less than the above-described lower limit, the cohesiveness of the solder particles in the solder bonding process can be ensured. Also, the content of the fluxing agent in the bonding sheet is, for example, 50 parts by mass or less, preferably 20 parts by mass or less, more preferably 17.5 parts by mass or less, further more preferably 15 parts by mass or less, particularly preferably 12.5 parts by mass or less, more preferably 10 parts by mass or less with respect to 100 parts by mass of the matrix resin. Also, the ratio of the fluxing agent in the bonding sheet is, for example, 50% by mass or less, preferably 20% by mass or less, more preferably 10% by mass or less, further more preferably 8% by mass or less, particularly preferably 7% by mass or less, most preferably 5% by mass or less. When the content of the fluxing agent is not more than the above-described upper limit, the moldability of the bonding sheet is excellent.

When the oxygen concentration of the solder particles is defined as x₁ ppm and the content of the fluxing agent with respect to 100 parts by weight of the solder particles is defined as y₁ mmol, the bonding sheet preferably satisfies the following formula (1):

$$\\ \begin{matrix}0.045 \leq {y}_{1} / {x}_{1} \leq 0.09 & ( 1 )\end{matrix}$$

The above-described y₁/x₁ is, for example, 0.045 or more, preferably 0.050 or more, and for example, 0.099 or less, preferably 0.090 or less, more preferably 0.080 or less. When the y₁/x₁ is within the above-described range, the solder particles are easily accumulated, and the increase in resistance caused by corrosion of the solder portion after connection can be suppressed due to less excess acid.

When the median size (D₅₀) of the solder particles is defined as x₂ μm and the content of the fluxing agent with respect to 100 parts by weight of the solder particles is defined as y₂ mol, the bonding sheet preferably satisfies the following formula (2):

$$\\ \begin{matrix}0.15 < {x}_{2} {y}_{2} < 0.3 & ( 2 )\end{matrix}$$

The above-described x₂y₂ is, for example, 0.150 or more, preferably 0.155 or more, more preferably 0.157 or more, and for example, 0.314 or less, preferably 0.300 or less, more preferably 0.270 or less. When the x₂y₂ is within the above-described range, the solder particles are easily accumulated, and the increase in resistance caused by corrosion of the solder portion after connection can be suppressed due to less excess acid.

The fluxing agent is unevenly distributed around the solder particles in the matrix resin. That is, the fluxing agent is distributed in the matrix resin at a higher concentration around the solder particles than in portions other than around the solder particles. The phrase “around the solder particles” specifically means a range which is twice, preferably 1.5 times the diameter of the solder particle, and the phrase “a higher concentration around the solder particles than in portions other than around the solder particles” means that the highest concentration around the solder particles is twice, preferably 5 times the lowest concentration in portions other than around the solder particles. The concentration distribution can be confirmed, for example, by a scanning electron microscope (SEM). Thus, when the fluxing agent is unevenly distributed around the solder particles, the oxide films on the surfaces of the solder particles can be efficiently removed and the solder particles can be aggregated. Since the fluxing agent is unevenly distributed around the solder particles, excess fluxing agent other than around the solder particles can be reduced, and the increase in resistance of the solder portion can be suppressed.

The fluxing agent that is unevenly distributed around the solder particles preferably contains a metal derived from the solder particles. The metal derived from the solder particles corresponds to the kind of the solder particles (solder metal) contained. For example, when tin and bismuth are contained as the solder particles, the metals are tin and bismuth. An example of a method for measuring the metal derived from the solder particles includes energy dispersive X-ray analysis (EDX). A content of the solder particles in the fluxing agent is, for example, 50 parts by mass or more, preferably 100 parts by mass or more, and for example, 500 parts by mass or less, preferably, 300 parts by mass or less with respect to 100 parts by mass of the matrix resin. When the content of the solder particles is within the above-described range, the oxide films of the solder particles can be efficiently removed and the solder particles can be accumulated without forming a bridge to an electrode.

In addition to the above components, the bonding sheet of the present invention can contain, for example, a curing agent and/or a curing accelerator for the thermosetting resin, and from the viewpoint of improving adhesion strength of the solder particles to the thermoplastic resin, an additive such as a silane coupling agent at appropriate proportions as required.

The bonding sheet can be produced by the following production method. This production method is one embodiment of a production method of the bonding sheet of the present invention.

First, the above-described fluxing agent is dissolved in a first solvent to prepare a fluxing agent solution (first step). The first solvent is a solvent capable of dissolving a fluxing agent and is selected according to the kind of fluxing agent.

The first solvent is not limited as long as it is a solvent in which the fluxing agent is dissolved. Examples of the first solvent include water, alcohols, carboxylic acids and ketones. Examples of the alcohol include methanol, ethanol, isopropyl alcohol, and butanol. Examples of the carboxylic acid include formic acid and acetic acid. Examples of the ketone include acetone, methyl ethyl ketone, and methyl isobutyl ketone. When a solid carboxylic acid at room temperature (25° C.) is used as the fluxing agent, as the first solvent, preferably, an alcohol or a ketone is used, and more preferably, acetone is used.

In the present production method, even relatively large flux particles can be appropriately used as the fluxing agent because the fluxing agent is dissolved in the first solvent in this step.

The fluxing agent solution has a fluxing agent concentration (non-volatile component concentration) of, for example, 10% by mass or more, preferably 20% by mass or more, more preferably 25% by mass or more, and for example, 50% by mass or less, preferably 40% by mass or less, more preferably 35% by mass or less from the viewpoint of mixing with another component in the following second step.

In the present production method, a second solvent is then mixed with the above-described matrix resin components (thermosetting resin, thermoplastic resin, and another component which is blended if necessary), the solder particles, and the fluxing agent solution to prepare a mixed composition (second step). The second solvent is preferably a solvent in which at least a portion of the fluxing agent is dissolved. Examples of the second solvent include ketones, alkyl esters, aliphatic hydrocarbons, and aromatic hydrocarbons. Preferably, a ketone is used. Examples of the ketone include acetone, methyl ethyl ketone, methyl isobutyl ketone, and cyclohexanone. Examples of the alkyl ester include methyl acetate, ethyl acetate, butyl acetate, isobutyl acetate, and amyl acetate. Examples of the aliphatic hydrocarbon include n-hexane, n-heptane, octane, cyclohexane, and methylcyclohexane. Examples of the aromatic hydrocarbon include toluene, xylene, and ethylbenzene. These second solvents may be used alone or in combination of two or more. The second solvent may be of the same kind as or different kind from the first solvent. The mixed composition has a solids concentration of, for example, 50% by mass or more, preferably 60% by mass or more, more preferably 65% by mass or more, and for example, 90% by mass or less, preferably 80% by mass or less, more preferably 75% by mass or less from the viewpoint of easy formation of a coated film in the following third step.

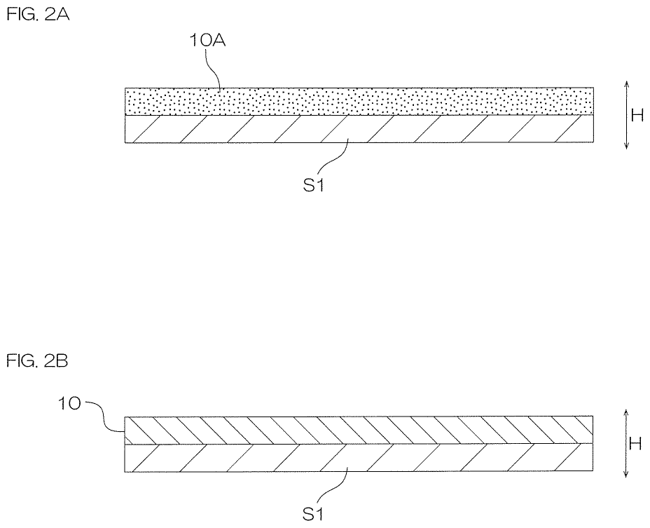

Next, as shown in FIG. 2A, the mixed composition is applied onto the substrate S1 to form a coated film 10A, and, as shown in FIG. 2B, the coated film 10A is dried to form the bonding sheet 10 (third step). An example of the substrate S1 includes a plastic film. Examples of the plastic film include polyethylene terephthalate films, polyethylene films, polypropylene films, and polyester films. The substrate preferably has a surface subjected to a surface release treatment.

In this step, the bonding sheet 10 is preferably dried by heating. A drying temperature is a softening temperature of the thermoplastic resin or more, below the melting points of the solder particles and the fluxing agent, and below the curing temperature of the thermosetting resin. The drying temperature is preferably 60° C. or more, more preferably 75° C. or more, and preferably 130° C. or less, more preferably 120° C. or less.

Before or after the third step, the substrate S2 may be laminated on top of the bonding sheet 10 on the substrate S1. As the substrate S2, the above-described plastic films for the substrate S1 can be used (a state in which the bonding sheet 10 is sandwiched between substrates S1 and S2 is illustrated in FIG. 1).

As described above, the bonding sheet 10 can be produced.

In the present production method, as described above, the fluxing agent is dissolved in the first solvent in the first step. In the second step, the fluxing agent is mixed with other components (matrix resin components and solder particles) in the state of being dissolved in the first solvent. Therefore, in the coated film formed in the third step, the fluxing agent is unevenly distributed around the solder particles in the matrix resin. As a result, the oxide films on the surfaces of the solder particles can be efficiently removed and the solder particles can be aggregated. Since the fluxing agent is unevenly distributed around the solder particles, an excess amount of the fluxing agent other than around the solder particles can be reduced, and the increase in resistance of the solder portion can be suppressed.

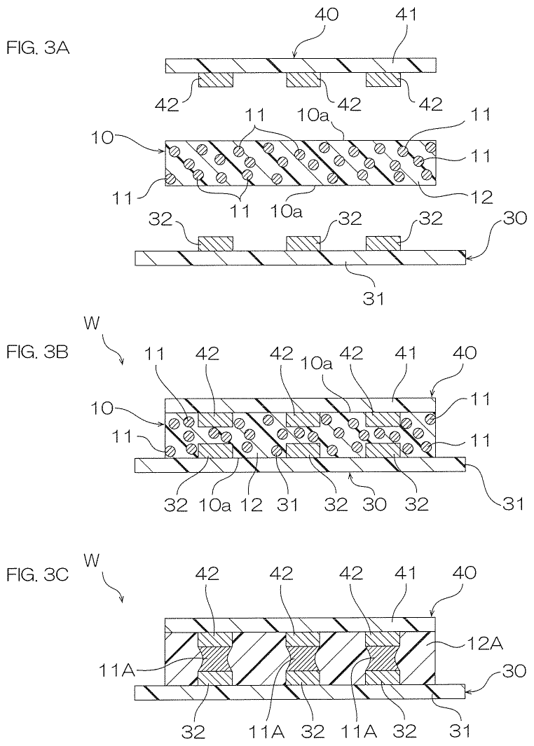

FIG. 3 shows one example of a solder bonding method using the bonding sheet 10.

In the present method, first, as shown in FIG. 3A, a wiring circuit board 30, an electronic component 40, and the bonding sheet 10 are prepared (preparation step). The wiring circuit board 30 is one example of one object to be bonded, and has a substrate 31 and a plurality of terminals 32. The substrate 31 is, for example, an insulating substrate having a flat plate shape. The terminal 32 is made of metal. The plurality of terminals 32 are isolated from each other.

The maximum length of the terminal 32 is, for example, 10 μm or more, and for example, 200 μm or less.

An interval between the terminals 32 is, for example, 10 μm or more, and for example, 200 μm or less. The electronic component 40 is one example of the other object to be bonded, and has a body portion 41 and a plurality of terminals 42. The terminal 42 is made of metal. The plurality of terminals 42 are isolated from each other. The plurality of terminals 42 are provided in an arrangement and size that can face the plurality of terminals 32 of the wiring circuit board 30. For the bonding sheet 10, solder particles 11 and a matrix resin 12 are illustrated.

Next, as shown in FIG. 3B, the wiring circuit board 30, the bonding sheet 10, and the electronic component 40 are laminated in this order (lamination step). Specifically, the wiring circuit board 30 and the electronic component 40 are compressively bonded via the bonding sheet 10 so that the corresponding terminals 32 and 42 are arranged facing each other, and the terminals 32 and 42 are buried in the bonding sheet 10. Thus, a laminate W is obtained. The wiring circuit board 30 and the electronic component 40 are temporarily bonded via the bonding sheet 10.

Next, by heating the laminate W, as shown in FIG. 3C, a solder portion 11A is formed between each of the terminals 32 and 42 (heating step). A heating temperature is the melting points of the solder particles 11 and the fluxing agent or more, the softening point of the thermoplastic resin or more, and the curing temperature of the thermosetting resin or more. The heating temperature is appropriately determined according to the kinds of thermosetting resin, thermoplastic resin, solder particles, and fluxing agent, and is, for example, 120° C. or more, preferably 130° C. or more, and for example, 170° C. or less, preferably 160° C. or less. Further, the heating time is, for example, 3 seconds or more, and for example, 60 seconds or less, preferably 30 seconds or less.

By the short-time heating as described above in the heating step, in the bonding sheet 10, the thermoplastic resin is melted once, and the fluxing agent is melted to develop the oxide film removal function of the surfaces of the solder particles. Then, the solder particles are melted and aggregated, and then gather between the terminals 32 and 42 and are aggregated (self-alignment). Curing of the thermosetting resin progresses around the solder material where the particles are aggregated. By lowering the temperature after the completion of the heating step, the solder material where the particles are aggregated between the terminals 32 and 42 coagulates, thereby forming the solder portion 11A. Thus, the terminals 32 and 42 are electrically connected by the solder portion 11A, while the wiring circuit board 30 is bonded to the electronic component 40 by the bonding sheet 10. A cured resin portion 12A derived from the matrix resin 12 is formed around the solder portion 11A. The cured resin portion 12A contains a thermosetting resin in which the curing progresses at least partially and a solidified thermoplastic resin, and preferably contains a thermosetting resin in a fully cured state and a solidified thermoplastic resin.

As described above, it is possible to mount the electronic component 40 on the wiring circuit board 30 using the bonding sheet 10.

### Function and Effects

In conventional bonding sheets, the fluxing agent is uniformly dispersed throughout matrix resins (thermoplastic resin and thermosetting resin), besides around the solder particles. That is, in the bonding sheet, in addition to the fluxing agent that exists around the solder particles and contributes to the removal of the oxide films of the solder particles, there is excess fluxing agent that does not exist around the solder particles and does not contribute to the removal of the oxide films of the solder particles. In this case, the amount of the fluxing agent required becomes large as compared to a case where the fluxing agent is unevenly distributed around the solder particles because solder particles dispersed throughout the matrix resin need to reach the surfaces of the solder particles. As a result, there is a disadvantage in that resistance values increase due to metal corrosion of the solder portion caused by such excess fluxing agent.

However, in the bonding sheet 10, as shown in the enlarged view of FIG. 1, a fluxing agent 13 is unevenly distributed around the solder particle 11 in the matrix resin 12. Therefore, it is possible to reduce the amount of excess fluxing agent which is other than the fluxing agent required to efficiently remove the oxide films on the surfaces of the solder particles. This can result in suppression of the increase in resistance of the solder portion due to excess fluxing agent. As a result, durability can be improved.

In the present production method, the fluxing agent is dissolved in the first solvent in the first step. Therefore, as the bonding sheet 10 dries, the fluxing agent is unevenly distributed around the solder particles in the matrix resin. As a result, the overall amount of the fluxing agent required can be suppressed, and the increase in resistance of the solder portion can be suppressed.

### Modified Examples

In the embodiment of FIG. 3A, the bonding sheet 10 is disposed between the electronic component 40 and the wiring circuit board 30 in the lamination of the bonding sheet 10 to the electronic component 40 and to the wiring circuit board 30. However, for example, though not shown, lamination may be performed by stacking the bonding sheet 10 on the wiring circuit board 30 at one side so that the terminals 32 of the wiring circuit board 30 are in contact with the bonding sheet 10, and then stacking the electronic component 40 on the bonding sheet 10 so that the terminals 42 are in contact with the bonding sheet 10. That is, the bonding sheet 10 and the electronic component 40 at the other side may be sequentially laminated on the wiring circuit board 30 at one side. In the bonding method described above, an electronic component is produced by bonding the electronic component 40 and the wiring circuit board 30 via the bonding sheet 10, but an electronic component can also be produced by bonding the wiring circuit board 30 and another wiring circuit board via the bonding sheet 10.

### EXAMPLE

Hereinafter, the present invention will be described in further detail with reference to Examples and Comparative Examples, but not limited these Examples and Comparative Examples.

### Example 1

A bonding sheet of Example 1 was fabricated as follows.

First, as a fluxing agent, malic acid (particle size D₅₀ of 4.4 μm, melting point of 130° C., solid at room temperature (25° C.)) was added to a solvent (acetone) and dissolved to prepare a fluxing agent solution having a solids concentration (non-volatile component concentration) of 33% by mass (first step).

Then, as a thermosetting resin, 60 parts by mass of an epoxy resin (trade name “jER828”, bisphenol A type epoxy resin, epoxy equivalent of 184 to 194 g/eq, liquid at room temperature (25° C.), manufactured by Mitsubishi Chemical Corporation); as a thermoplastic resin, 40 parts by mass of an acrylic resin (trade name “ARUFON UH-2170”, hydroxy group-containing styrene acrylic polymer, solid at room temperature (25° C.), manufactured by Toagosei Co., Ltd.); 150 parts by mass of solder particles (42% by mass of Sn-58% by mass of Bi alloy, melting point of 139° C., spherical shape, particle size D₅₀ of 3 μm, oxygen concentration of 1100 ppm); and the fluxing agent solution were added to methyl ethyl ketone (MEK) to be mixed, thereby preparing a mixed composition having a solids concentration of 72% by mass (second step). A content of the fluxing agent in this mixed composition is 10 parts by mass.

Next, the mixed composition was applied onto a substrate (release liner) to form a coated film, and the coated film was then dried (third step). The drying temperature was 80° C., and the drying time was 5 minutes. Thus, a bonding sheet having a thickness of 10 μm was formed on the substrate (release liner). The composition of the bonding sheet of Example 1 is shown in Table 1 (the compositions of the bonding sheets of the following Examples and Comparative Examples are also shown in Tables 1 and 2). In Tables 1 and 2, the unit of each numerical value representing the composition is relative “parts by mass”.

### Example 2

A bonding sheet was fabricated in the same manner as the bonding sheet of Example 1, except that in the second step, the blending amount of the fluxing agent (malic acid) in the mixed composition was changed to 17.5 parts by mass instead of 10 parts by mass, to prepare a mixed composition having a solids concentration of 63% by mass (second step).

### Example 3

A bonding sheet of Example 3 was fabricated in the same manner as the bonding sheet of Example 1, except that in the second step, the blending amount of the fluxing agent (malic acid) in the mixed composition was changed to 20 parts by mass instead of 10 parts by mass, to prepare a mixed composition having a solids concentration of 61% by mass (second step).

### Example 4

A bonding sheet of Example 4 was fabricated in the same manner as the bonding sheet of Example 1, except that in the first step, malonic acid (particle size D₅₀ of 4.5 μm, melting point of 135° C., solid at room temperature (25° C.)) was used instead of the malic acid as the fluxing agent; and in the second step, 10 parts by mass of the fluxing agent (malonic acid) was blended instead of 10 parts by mass of the fluxing agent (malic acid) in the mixed composition, to prepare a mixed composition having a solids concentration of 72% by mass (second step).

### Example 5

A bonding sheet of Example 5 was fabricated in the same manner as the bonding sheet of Example 1, except that in the first step, malonic acid was used instead of the malic acid as the fluxing agent; and in the second step, 20 parts by mass of the fluxing agent (malonic acid) was blended instead of 10 parts by mass of the fluxing agent (malic acid) in the mixed composition, to prepare a mixed composition having a solids concentration of 61% by mass (second step).

### Example 6

A bonding sheet of Example 6 was fabricated in the same manner as the bonding sheet of Example 1, except that in the second step, as the solder particles in the mixed composition, solder particles (42% by mass of Sn-58% by mass of Bi alloy, melting point of 139ºC, spherical shape, particle size D₅₀ of 5 μm, oxygen concentration of 650 ppm) were used to prepare a mixed composition having a solids concentration of 72% by mass (second step).

### Example 7

A bonding sheet of Example 7 was fabricated in the same manner as the bonding sheet of Example 1, except that in the second step, 17.5 parts by mass of the fluxing agent (malic acid) was blended instead of 10 parts by mass of the fluxing agent (malic acid) in the mixed composition, and as the solder particles in the mixed composition, solder particles (42% by mass of Sn-58% by mass of Bi alloy, melting point of 139° C., spherical shape, particle size D₅₀ of 3 μm, oxygen concentration of 1500 ppm) were used to prepare a mixed composition having a solids concentration of 61% by mass (second step).

### Example 8

A bonding sheet of Example 8 was fabricated in the same manner as the bonding sheet of Example 1, except that in the second step, 20 parts by mass of the fluxing agent (malic acid) was blended instead of 10 parts by mass of the fluxing agent (malic acid) in the mixed composition, and as the solder particles in the mixed composition, solder particles (42% by mass of Sn-58% by mass of Bi alloy, melting point of 139° C., spherical shape, particle size D₅₀ of 3 μm, oxygen concentration of 1500 ppm) were used to prepare a mixed composition having a solids concentration of 61% by mass (second step).

### Example 9

A bonding sheet of Example 9 was fabricated in the same manner as the bonding sheet of Example 1, except that in the second step, as the solder particles in the mixed composition, solder particles (42% by mass of Sn-58% by mass of Bi alloy, melting point of 139ºC, spherical shape, particle size D50 of 3 μm, oxygen concentration of 300 ppm) were used to prepare a mixed composition having a solids concentration of 61% by mass (second step).

### Example 10

A bonding sheet of Example 10 was fabricated in the same manner as the bonding sheet of Example 1, except that in the second step, as the solder particles in the mixed composition, solder particles (42% by mass of Sn-58% by mass of Bi alloy, melting point of 139ºC, spherical shape, particle size D50 of 7 μm, oxygen concentration of 500 ppm) were used to prepare a mixed composition having a solids concentration of 72% by mass (second step).

### Comparative Example 1

As a thermosetting resin, 60 parts by mass of an epoxy resin (trade name “jER828”, bisphenol A type epoxy resin, epoxy equivalent of 184 to 194 g/eq, liquid at room temperature (25° C.), manufactured by Mitsubishi Chemical Corporation); as a thermoplastic resin, 40 parts by mass of an acrylic resin (trade name “ARUFON UH-2170”, hydroxy group-containing styrene acrylic polymer, solid at room temperature (25° C.), manufactured by Toagosei Co., Ltd.); 150 parts by mass of solder particles (42% by mass of Sn-58% by mass of Bi alloy, melting point of 139° C., spherical shape, particle size D₅₀ of 3 um, oxygen concentration of 1100 ppm); and 50 parts by mass of a fluxing agent (malic acid) were added to methyl ethyl ketone (MEK) to be mixed, thereby preparing a mixed composition having a solids concentration of 70% by mass.

Next, the mixed composition was applied onto a substrate (release liner) to form a coated film, and the coated film was then dried (third step). The drying temperature was 80° C., and the drying time was 5 minutes. Thus, a bonding sheet having a thickness of 10 μm was formed on the substrate (release liner).

### Comparative Example 2

A bonding sheet was fabricated in the same manner as the bonding sheet of Comparative Example 1, except that the blending amount of the fluxing agent (malic acid) in the mixed composition was changed to 20 parts by mass instead of 50 parts by mass.

### Comparative Example 3

A bonding sheet was fabricated in the same manner as the bonding sheet of Comparative Example 1, except that the blending amount of the fluxing agent (malic acid) in the mixed composition was changed to 17.5 parts by mass instead of 50 parts by mass.

### Comparative Example 4

A bonding sheet was fabricated in the same manner as the bonding sheet of Comparative Example 1, except that the blending amount of the fluxing agent (malic acid) in the mixed composition was changed to 10 parts by mass instead of 50 parts by mass.

### Scanning Electron Microscope (SEM) Observation

A cross section of a sample was prepared as follows. The cross section of the sample was adjusted by irradiating a Ga ion beam using an FIB-SEM system (“Helios G4 UX”, manufactured by Thermo Fisher Scientific Inc.) under conditions of an acceleration voltage of 30 kV and a temperature of −160° C. A reflected electron image of the cross section of the bonding sheet adjusted as described above was obtained using an FIB-SEM system (“Helios G4 UX”, manufactured by Thermo Fisher Scientific Inc.) under conditions of an acceleration voltage of 2 kV and a temperature of −160° C.

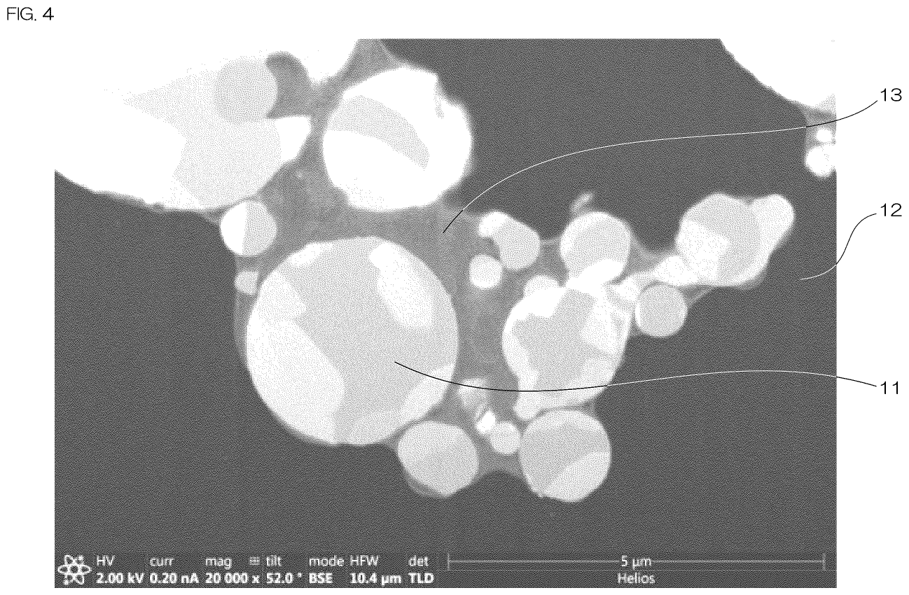

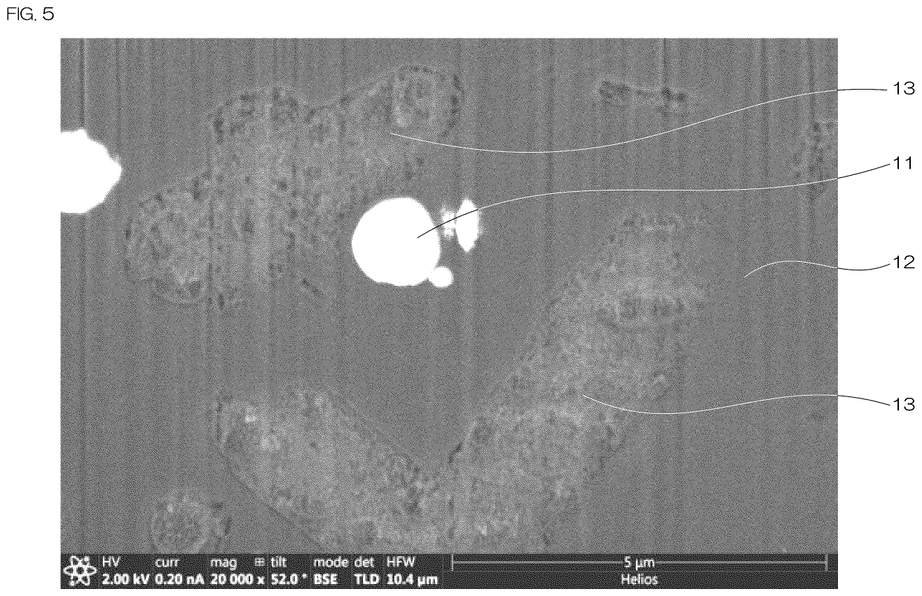

The cross sections of the bonding sheets of Example 1 and Comparative Example 1 were observed by a scanning electron microscope (SEM). An image-processed scanning electron microscope (SEM) photograph of Example 1 is shown in FIG. 4. An image-processed scanning electron microscope (SEM) photograph of Comparative Example 1 is shown in FIG. 5.

In FIG. 4, the solder particles 11 were dispersed in the matrix resin 12, and the fluxing agent 13 was unevenly distributed around the solder particles 11 in the matrix resin 12.

In FIG. 5, although the solder particles 11 were dispersed in the matrix resin 12, the fluxing agent 13 was not unevenly distributed around the solder particles 11 in the matrix resin 12.

### Energy Dispersive X-Ray Analysis (EDX)

Regarding a sample cross-sectioned in the same manner as in the SEM observation, elemental mapping of the cross-sectional area of the sample was performed using an EDX system (“Energy-XMAX 150”, manufactured by Oxford Instruments) under conditions of an acceleration voltage of 7 kV and a temperature of −160° C.

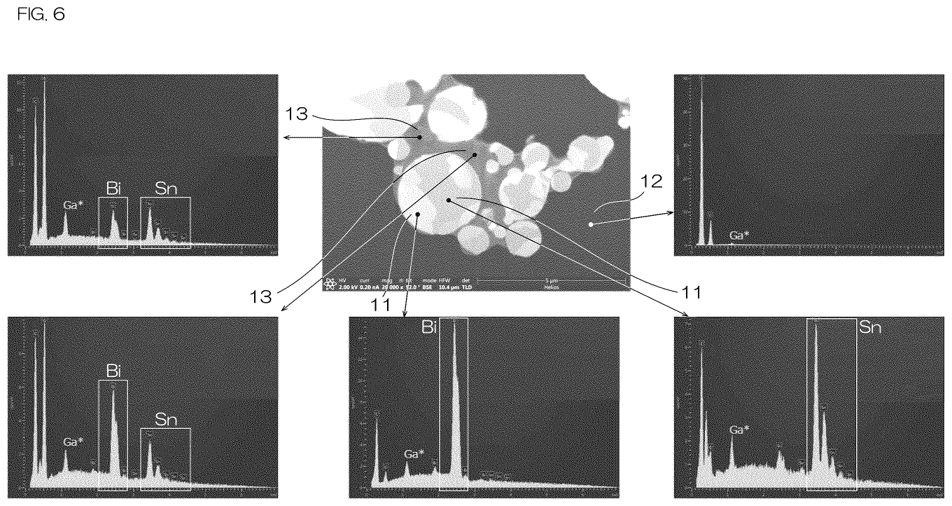

The energy dispersive X-ray analysis (EDX) was performed on the cross section of the bonding sheet of Example 1. An image-processed photograph of the energy dispersive X-ray analysis (EDX) is shown in FIG. 6.

The top center image of FIG. 6 shows an image-processed scanning electron microscope (SEM) photograph of the cross section of the bonding sheet of Example 1.

The top right image of FIG. 6 is an image-processed photograph of the energy dispersive X-ray analysis (EDX) showing the presence or absence of metals (Bi, Sn) derived from the solder particles 11 in the matrix resin 12 portion. As shown in the top right image of FIG. 6, no metals (Bi, Sn) derived from the solder particles 11 were detected in the matrix resin 12 portion.

The bottom right image of FIG. 6 is an image-processed photograph of the energy dispersive X-ray analysis (EDX) showing the presence or absence of the metals (Bi, Sn) of the solder particles 11 in the solder particle 11 portion. As shown in the bottom right image of FIG. 6, Sn which is a metal of the solder particles 11 was detected in the Sn-rich phase of the solder particles 11.

The bottom center image of FIG. 6 is an image-processed photograph of the energy dispersive X-ray analysis (EDX) showing the presence or absence of the metals (Bi, Sn) of the solder particles 11 in the solder particle 11 portion. As shown in the bottom center image of FIG. 6, Bi which is a metal of the solder particles 11 was detected in the Bi-rich phase of the solder particles 11.

The bottom left image of FIG. 6 is an image-processed photograph of the energy dispersive X-ray analysis (EDX) showing the presence or absence of the metals (Bi, Sn) derived from the solder particles 11 in the fluxing agent 13 portion. As shown in the bottom left image of FIG. 6, the metals (Bi, Sn) derived from the solder particles 11 were detected in the fluxing agent 13 portion.

The top left image of FIG. 6 is an image-processed photograph of the energy dispersive X-ray analysis (EDX) showing the presence or absence of the metals (Bi, Sn) derived from the solder particles 11 in the fluxing agent 13 portion. As shown in the top left image of FIG. 6, the metals (Bi, Sn) derived from the solder particles 11 were detected in the fluxing agent 13 portion.

### Evaluation of Accumulation

Each bonding sheet was evaluated for accumulation of the solder particles by heating. First, two wiring circuit boards were attached to each other via a bonding sheet, thereby preparing a sample. Each of the wiring circuit boards had a transparent glass substrate, and a plurality of terminals (width of 30 μm) formed thereon. The plurality of terminals are disposed in parallel on one surface of the glass substrate (space between adjacent terminals of 30 μm). In the sample, the two wiring circuit boards were bonded to each other via the bonding sheet so that a terminal of one wiring circuit board faced a terminal of the other wiring circuit board. Next, the sample was subjected to a heat treatment at 160° C. for 30 seconds. During the heat treatment, by using a digital microscope (trade name “VHX-7000”, manufactured by KEYENCE CORPORATION), the bonding sheet between the wiring circuit boards in the sample was observed at an enlargement magnification of 200 times. An accumulation state of the solder particles after the 30-second heat treatment was evaluated. The evaluation criteria were based on the following levels from 1 to 4.
1: All solder particles were accumulated and no unaccumulated solder particles were observed between the terminals.
2: Solder particles were accumulated, but unaccumulated solder particles were observed between the terminals.
3: Solder particles were accumulated, but more than half of the solder particles were unaccumulated.
4: Almost no accumulation of solder particles was observed.
   The results are shown in Tables 1 and 2.

### Durability Evaluation by Resistance Measurement

Each bonding sheet was evaluated for durability by resistance measurement as follows. First, two wiring circuit boards were attached to each other via a bonding sheet, thereby preparing a sample. Each of the wiring circuit boards had a transparent glass substrate, and a plurality of terminals (width of 30 μm) formed thereon. The plurality of terminals are disposed in parallel on one surface of the glass substrate (space between adjacent terminals of 30 μm). In the sample, the two wiring circuit boards were bonded to each other via the bonding sheet so that a terminal of one wiring circuit board faced a terminal of the other wiring circuit board. Next, the sample was subjected to a heat treatment at 160° C. for 20 seconds. Next, after lowering the temperature of the sample, a resistance value between the facing one pair of terminals via the bonding sheet through the heat treatment was measured and the measured value was determined as a resistance value before a durability test. Thereafter, the sample was allowed to stand in a constant temperature/humidity chamber at 60° C. and 90% relative humidity (RH) for 3 weeks. Then, the sample was taken out, and the resistance value was measured in the same manner in the room temperature environment (25° C., 50% RH) to determine the measured value as a resistance value after the durability test. A digital multimeter PC-500a (manufactured by Sanwa Electric Instrument Co., Ltd.) was used to measure the resistance values. A case where the resistance value after the durability test was more than 15 times the resistance value before the durability test, the durability was evaluated as X, a case where it was more than 10 times and 15 times or less the resistance value before the durability test, the durability was evaluated as Δ, a case where it was more than once and 10 times or less the resistance value before the durability test, the durability was evaluated as ◯, and a case where the resistance value was not changed, the durability was evaluated as ⊚. The bonding sheets of Comparative Examples 3 and 4 were not evaluated for durability because the solder particles were not sufficiently accumulated. X and Δ result from increased resistance values due to corrosion of the solder metal caused by excess fluxing agent.

### Flux Uneven Distribution State

The flux uneven distribution state was evaluated as follows. Examples of the evaluation using acetone-dissolved malic acid (Example 1) and powdered malic acid (Comparative Example 2) are shown. For the examples of Example 1 and Comparative Example 2, images observed by the scanning electron microscope were evaluated using an image processing software “Image J”.

An area from the center portion of the solder particle to a portion 1.5 times the solder particle diameter was cut out, and an area ratio (a proportion of the flux portion) of the resin portion (the portion excluding the solder particles) to the flux portion was calculated. For a portion corresponding to the rest of the area, a similar sized portion was cut out and the proportion of the flux portion was calculated.

To evaluate the uneven distribution state, the proportion of the flux portion on the periphery of the solder particles was compared to the proportion of the flux portion other than the periphery.

The results were evaluated as ⊚ a case where (proportion of flux portion on the periphery of solder particles)/(proportion of flux portion other than the periphery) was more than 5 times, as ◯ a case where it was twice or more and less than 5 times, and as X otherwise. The results are shown in Tables 1 and 2.

TABLE 1

| | | Ex. 1 | Ex. 2 | Ex. 3 | Ex. 4 | Ex. 5 | Ex. 6 | Ex. 7 |
|---|---|---|---|---|---|---|---|---|
| Composition | Epoxy (jER 828) | 60 | 60 | 60 | 60 | 60 | 60 | 60 |
| of | Acrylic (UH2170) | 40 | 40 | 40 | 40 | 40 | 40 | 40 |
| bonding | Powdered malic acid | — | — | — | — | — | — | — |
| sheet | Acetone-dissolved malic acid | 10 | 17.5 | 20 | — | — | 10 | 17.5 |
| (parts | (Solid content) | | | | | | | |
| by | Dissolved malonic acid | — | — | — | 10 | 20 | — | — |
| weight) | (Solid content) | | | | | | | |
| | Sn42—Bi58 (solder particles) | — | — | — | — | — | — | — |
| | Oxygen concentration of 500 ppm, | | | | | | | |
| | particle size of 7 μm | | | | | | | |
| | Sn42—Bi58 (solder particles) | — | — | — | — | — | 150 | — |
| | Oxygen concentration of 650 ppm, | | | | | | | |
| | particle size of 5 μm | | | | | | | |
| | Sn42—Bi58 (solder particles) | — | — | — | — | — | — | — |
| | Oxygen concentration of 300 ppm, | | | | | | | |
| | particle size of 3 μm | | | | | | | |
| | Sn42—Bi58 (solder particles) | 150 | 150 | 150 | 150 | 150 | — | — |
| | Oxygen concentration of 1100 ppm, | | | | | | | |
| | particle size of 3 μm | | | | | | | |
| | Sn42—Bi58 (solder particles) | — | — | — | — | — | — | 150 |
| | Oxygen concentration of 1500 ppm, | | | | | | | |
| | particle size of 3 μm | | | | | | | |

| | | | | | | | |
|---|---|---|---|---|---|---|---|
| y₁/x₁ | 0.050 | 0.086 | 0.099 | 0.064 | 0.127 | 0.061 | 0.063 |
| x₂y₂ | 0.157 | 0.276 | 0.314 | 0.202 | 0.404 | 0.261 | 0.276 |
| Evaluation of acculation | 1 | 1 | 1 | 1 | 2 | 1 | 1 |
| Durability evaluation by | ⊚ | ◯ | Δ | ⊚ | Δ | ⊚ | ◯ |
| resistance measurement | | | | | | | |
| Flux uneven distribution state | ⊚ | ⊚ | ◯ | ⊚ | ◯ | ⊚ | ⊚ |

TABLE 2

| | | | | | Comp. | Comp. | Comp. | Comp. |
|---|---|---|---|---|---|---|---|---|
| | | Ex. 8 | Ex. 9 | Ex. 10 | Ex. 1 | Ex. 2 | Ex. 3 | Ex. 4 |
| Composition | Epoxy (jER 828) | 60 | 60 | 60 | 60 | 60 | 60 | 60 |
| of | Acrylic (UH2170) | 40 | 40 | 40 | 40 | 40 | 40 | 40 |
| bonding | Powdered malic acid | — | — | — | 50 | 20 | 17.5 | 10 |
| sheet | Acetone-dissolved malic acid | 20 | 10 | 10 | — | — | — | — |
| (parts | (Solid content) | | | | | | | |
| by | Dissolved malonic acid | — | — | — | — | — | — | — |
| weight) | (Solid content) | | | | | | | |
| | Sn42—Bi58 (solder particles) | — | — | 150 | — | — | — | — |
| | Oxygen concentration of 500 ppm, | | | | | | | |
| | particle size of 7 μm | | | | | | | |
| | Sn42—Bi58 (solder particles) | — | — | — | — | — | — | — |
| | Oxygen concentration of 650 ppm, | | | | | | | |
| | particle size of 5 μm | | | | | | | |
| | Sn42—Bi58 (solder particles) | — | 150 | — | — | — | — | — |
| | Oxygen concentration of 300 ppm, | | | | | | | |
| | particle size of 3 μm | | | | | | | |
| | Sn42—Bi58 (solder particles) | — | — | — | 150 | 150 | 150 | 150 |
| | Oxygen concentration of 1100 ppm, | | | | | | | |
| | particle size of 3 μm | | | | | | | |
| | Sn42—Bi58 (solder particles) | 150 | — | — | — | — | — | — |
| | Oxygen concentration of 1500 ppm, | | | | | | | |
| | particle size of 3 μm | | | | | | | |

| | | | | | | | |
|---|---|---|---|---|---|---|---|
| y₁/x₁ | 0.073 | 0.132 | 0.079 | 0.248 | 0.099 | 0.086 | 0.050 |
| x₂y₂ | 0.314 | 0.276 | 0.366 | 0.786 | 0.314 | 0.276 | 0.157 |
| Evaluation of acculation | 1 | 1 | 1 | 1 | 2 | 3 | 4 |
| Durability evaluation by | Δ | ⊚ | ⊚ | X | Δ | (—) | (—) |
| resistance measurement | | | | | | | |
| Flux uneven distribution state | ◯ | ⊚ | ⊚ | X | X | X | X |

While the illustrative embodiments of the present invention are provided in the above-described invention, such is for illustrative purpose only and it is not to be construed restrictively. Modification and variation of the present invention that will be obvious to those skilled in the art is to be covered by the following claims.

### INDUSTRIAL APPLICABILITY

The bonding sheet and the method for producing the bonding sheet according to the present invention are suitably used, for example, in bonding a terminal of a wiring circuit board to a terminal of an electronic component, and in bonding between terminals of two wiring circuit boards.

### DESCRIPTION OF REFERENCE NUMERALS

10 bonding sheet
10a surface
H thickness direction
10A coated film
11 solder particles
11A solder portion
12 matrix resin
12A cured resin portion
13 fluxing agent
S1, S2 substrate
30 wiring circuit board
40 electronic component

1. A bonding sheet, comprising a matrix resin; solder particles; and a fluxing agent,
the solder particles being dispersed in the matrix resin, and
the fluxing agent being unevenly distributed around the solder particles in the matrix resin.

2. The bonding sheet according to claim 1, wherein the fluxing agent unevenly distributed around the solder particles contains a metal derived from the solder particles.

3. The bonding sheet according to claim 1 or 2, wherein when an oxygen concentration of the solder particles is defined as x₁ ppm and a content of the fluxing agent with respect to 100 parts by weight of the solder particles is defined as y₁ mmol, the bonding sheet satisfies the following formula (1):
$$\\ \begin{matrix}0.045 \leq {y}_{1} / {x}_{1} \leq 0.09 & ( 1 )\end{matrix}$$

4. The bonding sheet according to any one of claims 1 to 3, wherein when a median size (D₅₀) of the solder particles is defined as x₂ μm and a content of the fluxing agent with respect to 100 parts by weight of the solder particles is defined as y₂ mol, the bonding sheet satisfies the following formula (2):
$$\\ \begin{matrix}0.15 < {x}_{2} {y}_{2} < 0.3 & ( 2 )\end{matrix}$$

5. The bonding sheet according to any one of claims 1 to 4, wherein the fluxing agent is a solid carboxylic acid at 25° C.

6. The bonding sheet according to any one of claims 1 to 5, wherein the solder particles have a melting point of 150° C. or less.

7. The bonding sheet according to any one of claims 1 to 6, having a thickness of 30 μm or less.

8. A method for producing a bonding sheet, comprising a first step of dissolving a fluxing agent in a first solvent to prepare a fluxing agent solution;
a second step of mixing a second solvent, a matrix resin component, solder particles, and the fluxing agent solution to prepare a mixed composition; and
a third step of applying the mixed composition onto a substrate to form a coated film, and then drying the coated film to form a bonding sheet.
